(19) United States
(12) Patent Application Publication
(10) Pub. No.: US 2015/0167148 A1
(43) Pub. Date: Jun. 18, 2015

(54) Method for Synthesis of Uniform Bi-Layer and Few-Layer Hexagonal Boron Nitride Dielectric Films

(71) Applicant: Brookhaven Science Associates, LLC, Upton, NY (US)

(72) Inventors: Peter Werner Sutter, Westhampton Beach, NY (US); Eli Anguelova Sutter, Westhampton Beach, NY (US)

(21) Appl. No.: 14/572,928

(22) Filed: Dec. 17, 2014

Related U.S. Application Data
(60) Provisional application No. 61/917,044, filed on Dec. 17, 2013.

(51) Int. Cl. C23C 14/06; C23C 14/35

(52) U.S. Cl. CPC C23C 14/0647; C23C 14/35

(57) ABSTRACT

A method for forming high quality hexagonal boron-nitride films with multiple layers that are substantially parallel to the substrate and with substantially uniform layer thickness. In one embodiment, a bi-layer of boron-nitride is formed on a substrate by reactive radio frequency magnetron sputtering of a boron target in high-purity Ar/N₂ gas mixtures at elevated temperature. In another embodiment, few-layer boron nitride films are formed by alternatingly reactive radio frequency magnetron sputtering of a boron target in high-purity Ar/N₂ gas mixtures at room temperature and annealing at elevated temperature until a desired number of layers of high quality hexagonal boron nitride layers are formed on the substrate.

### CROSS REFERENCE TO RELATED APPLICATIONS

This application claims the benefit of U.S. Provisional Application No. 61/917,044 filed on Dec. 17, 2013, the contents of which are incorporated by reference herein in their entirety.

### STATEMENT OF GOVERNMENT RIGHTS

This invention was made with Government support under contract number DE-AC02-98CH10886, awarded by the U.S. Department of Energy. The United States Government has certain rights in the invention.

### FIELD OF THE INVENTION

This disclosure generally relates to the scalable synthesis of uniform thickness, high quality few-layer hexagonal boron nitride dielectric films. In particular, methods for forming high quality bi-layer and few-layer hexagonal boron-nitride thin films are disclosed. In particular, a high quality hexagonal boron-nitride film is disclosed, comprising two or more than two atomic layers of boron-nitride that are substantially parallel to a substrate and that have substantially equal and uniform layer thickness.

### BACKGROUND

Graphene, an atomically thin sheet of sp² bonded carbon, has attracted broad research interest, and its extreme properties promise to enable a wide range of future applications (Geim, A. K. “Graphene: Status and Prospects” Science, 2009, 324, 1530-1534; Castro Neto, A. H.; et al. “The electronic properties of grapheme” Rev. Mod. Phys. 2009, 81, 109). Among other two-dimensional or ultrathin layered materials (Novoselov, K. S. “Two-dimensional atomic crystals” Proc. Natl. Acad. Sci. U.S.A. 2005, 102, 10451-10453), boron nitride (BN) appears particularly well suited for integration with graphene, for instance as a gate dielectric for high-mobility field effect devices (Dean, C. R. “Boron nitride substrates for high-quality graphene electronics” Nat. Nanotechnol. 2010, 5, 722-726) or for designing novel layered heterostructures (Britnell, L. “Field-Effect Tunneling Transistor Based on Vertical Graphene Heterostructures” Science 2012, 335, 947-950). The two materials are isoelectronic and isostructural with minimal (˜1.6%) lattice mismatch (New Semiconductor Materials. Characteristics and Properties. http://www.ioffe.ru/SVA/NSM/Semicond/BN/(accessed Oct. 1, 2012)), yet have different band structures (semimetallic and insulating, respectively) giving rise to complementary (opto-) electronic characteristics.

Mechanical (Novoselov, K. S., 2005) or liquid-phase (Coleman, J. N. “Two-Dimensional Nanosheets Produced by Liquid Exfoliation of Layered Materials” Science 2011, 331, 568-571) exfoliation can provide high-quality single- and few-layer, small sized flakes of materials such as graphene and BN. However, the broader exploration of new phenomena and applications depends on the development of scalable synthesis methods for high quality layered materials.

Chemical vapor deposition (CVD) (Reina, A. “Large Area, Few-Layer Graphene Films on Arbitrary Substrates by Chemical Vapor Deposition” Nano Lett. 2009, 9, 30-35; Li, X. “Large-Area Synthesis of High-Quality and Uniform Graphene Films on Copper Foils” Science 2009, 324, 1312-1314) and carbon segregation (Sutter, P. W.; et al., “Epitaxial graphene on ruthenium” Nat. Mater. 2008, 7, 406-411) on transition metals are now among the primary methods for graphene synthesis. CVD methods have also been used for growing BN (Oshima, C.; Nagashima, A. “Ultra-thin epitaxial films of graphite and hexagonal boron nitride on solid surfaces” J. Phys: Condens. Matter 1997, 9, 1; Corso, M. “Boron Nitride Nanomesh” Science 2004, 303, 217-220) and hybrid graphene-BN monolayers, (See e.g. Sutter, P.; et al. “Interface Formation in Monolayer Graphene-Boron Nitride Heterostructures” Nano Lett 2012, 12, 4869-4874; Levendorf, M. P.; et al. “Graphene and boron nitride lateral heterostructures for atomically thin circuitry” Nature 2012, 488, 627-632), and recent reports have raised the possibility that such methods might be extended to the growth of few-layer BN (Song, L. “Large Scale Growth and Characterization of Atomic Hexagonal Boron Nitride Layers” Nano Lett. 2010, 10, 3209-3215; Shi, Y. “Synthesis of Few-Layer Hexagonal Boron Nitride Thin Film by Chemical Vapor Deposition” Nano Lett. 2010, 10, 4134-4139; and Lee, K. H. et al. “Large-Scale Synthesis of High-Quality Hexagonal Boron Nitride Nanosheets for Large-Area Graphene Electronics” Nano Lett. 2012, 12, 714-718). However, because of the low chemical reactivity of BN surfaces it is very difficult to achieve the controlled synthesis of few-layer BN films with thicknesses exceeding one atomic layer by CVD. After completion of an initial BN monolayer on a metal substrate, the further dissociation of CVD precursor gases is suppressed on the BN surface and the growth either self-terminates at a thickness of 1 atomic layer, or if additional layers are formed their thickness is non-uniform across the substrate. BN films with controlled thickness prepared by solution methods (Nag, A. “Graphene Analogues of BN: Novel Synthesis and Properties” ACS Nano 2010, 4, 1539-1544) show promise for applications in nanocomposites (Kiran, M. S. R. N.; et al “Improved mechanical properties of polymer nanocomposites incorporating graphene-like BN: Dependence on the number of BN layers” Scr. Mater. 2011, 64, 592-595), but it remains unclear if solution synthesis or vapor chemical routes with engineered precursors (Müller, F.; et al. “Epitaxial growth of hexagonal boron nitride monolayers by a three-step boration-oxidation-nitration process” Phys. Rev. B 2010, 82, 075405) can yield high quality BN at wafer scales.

No approach has yet provided methods for the controllable formation of high quality BN films with uniform thickness in the range of 2 to 30 BN atomic layers, crucial to their application as ultrathin dielectrics in novel device schemes in conjunction with graphene, such as bistable field-effect transistors (BisFETs) (Min, H.; et al. “Room-temperature superfluidity in graphene bilayers” Phys. Rev. B 2008, 78, 121401; Banerjee, S. K.; et al. “Bilayer PseudoSpin Field-Effect Transistor (BiSFET): A Proposed New Logic Device” IEEE Electron. Device Lett. 2009, 30, 158-160) or tunneling devices (Britnell, L.; 2012).

In view of the above, there exists a need in the art for a scalable synthesis of uniform few-layer hexagonal boron nitride dielectric films (Sutter, P.; et al.; “Scalable synthesis of uniform few-layer hexagonal boron nitride dielectric films” Nano Lett. 2013, 13:276-281, the contents of which are incorporated herein by reference, including the published Supplementary Online Material).

Each of the other publications cited in this application is incorporated by reference in its entirety as if fully set forth in this specification.

### SUMMARY

The present disclosure is directed to a method for forming high quality bi-layer and few-layer hexagonal boron-nitride films. A measure of quality of the few-layer hexagonal boron nitride (h-BN) film is the crystallinity, the uniformity of thickness of each of the layers of h-BN, composition with a 1:1 boron to nitrogen atomic ratio, completeness of coverage by each layer of said h-BN film, the realization of the large bandgap of h-BN, and the pinhole-free dielectric properties of the resulting few-layer films over large areas of at least more than 1 to about 5 μm². The expression “few-layer” refers to hexagonal boron-nitride (h-BN) film having more than two high quality layers of h-BN and up to about 30 high quality layers of h-BN. The method is scalable and adaptable to control the layer thickness of the hexagonal boron nitride dielectric film. The scalability and adaptability of the disclosed method can be achieved, for example, by using reactive radio frequency magnetron sputtering of boron in N₂/Ar with a scalable, industry-compatible process that uses benign, non-toxic reagents.

The disclosed method for forming high quality hexagonal boron-nitride films is essentially exemplified in FIG. 6, in particular FIG. 6(c), panels ii and iii. One embodiment of the method provides for forming a high quality bi-layer of hexagonal boron-nitride on a substrate. Said embodiment includes reactive radio frequency magnetron sputtering of a boron target in high-purity Ar/N₂ gas mixtures at elevated temperature (800° C. to about 1000° C.) under moderate (0.1 Torr) to high vacuum (10⁻⁴ Torr) for a time sufficient for formation of two layers of h-BN to form a bi-layer. The time sufficient for formation of the bi-layer of h-BN is the amount of time at the elevated temperature such that the deposition of h-BN becomes self-terminating at 2 atomic layers of thickness. This method includes a support substrate such as a ruthenium (Ru) film on Al₂O₃ substrate. In a preferred embodiment the support substrate is an epitaxial Ru film on a Al₂O₃ (0001) (c-plane sapphire).

An embodiment of the present method for forming, on a substrate, a high quality few-layer h-BN film having a desired number of layers includes two or more times alternatingly reactive radio frequency magnetron sputtering a boron target in high-purity Ar/N₂ gas mixtures at room temperature and annealing at elevated temperature for a number of times sufficient to form high quality few-layer h-BN film having the desired number of layers on the substrate. The sputtering may be under moderate to high vacuum. The elevated temperature may be from about 800° C. to about 1200° C.

An additional embodiment for forming, on a substrate, a high quality few-layer h-BN film having a desired number of layers includes first pre-forming a bilayer of h-BN on a substrate, and alternatingly depositing thereon a layer of boron-nitride by reactive radio frequency magnetron sputtering of a boron target in high-purity Ar/N₂ gas mixtures at room temperature and annealing the deposited layer at elevated temperature. The sputtering and annealing processes are repeated until the desired number of layers of h-BN has been formed on the pre-formed bilayer.

The present disclosure is also directed to a product that is a scalable, high quality, uniform few-layer hexagonal boron-nitride dielectric film. The hexagonal boron-nitride film comprises multiple layers of boron-nitride in which the number of atomic layers is constant over large sample areas, thus giving rise to a film of hexagonal boron nitride with overall uniform thickness. The hexagonal boron-nitride film can be substantially parallel to the substrate. Also, the few-layer hexagonal boron-nitride film can comprise planar atomic layers having substantially equal and uniform thickness.

These and other characteristics of the disclosed embodiments will become more apparent from the following description and illustrative embodiments which are described in detail with reference to the accompanying drawings.

### BRIEF DESCRIPTION OF THE DRAWINGS

FIG. 1(a)-(b) show a schematic diagram of hexagonal boron nitride growth by reactive magnetron sputtering, and a scanning electron micrograph of the surface of a boron nitride film growth by this method.

FIG. 2(a)-(c) show XPS analysis of 1-layer and 4-layer h-BN films on Ru(0001).

FIG. 3(a)-(c) show transmission electron microscopy results of A-A′-A stacked hexagonal BN on Ru(0001).

FIG. 4(a)-(c) show transmission electron microscopy results of A-B-C stacked rhombohedral BN on graphene-covered Ru(0001).

FIG. 5(a)-(b) show STM imaging of thin BN/Ru(0001) (˜1.3 atomic layers BN coverage) grown by magnetron sputtering at 850° C.

FIG. 6(a)-(c) show an XPS analysis of the deposition time-dependent thickness of BN on Ru(0001), illustrating the regimes of h-BN growth by chemical vapor deposition (single layer only) and reactive magnetron sputtering (bilayer) and alternating reactive magnetron sputtering at room temperature and high temperature annealing (few-layer BN).

FIG. 7 shows computational results on the reactivity of the surfaces of single- and bilayer h-BN on Ru(0001), and a comparison with bulk h-BN.

FIG. 8(a)-(b) show the analysis of the N1s XPS line shape resulting from room temperature BN deposition by reactive magnetron sputtering and the effect of annealing.

FIG. 9(a)-(b) show the analysis of the B1s XPS line shape resulting from room temperature BN deposition by reactive magnetron sputtering and the effect of annealing.

FIG. 10 shows UHV scanning electronmicroscopy image of a thicker (˜6 layer) BN film on Ru(0001).

FIG. 11(a)-(c) show optical UV/Vis and Raman spectroscopy on few-layer BN/Ru(0001).

FIG. 12(a)-(e) show vertical tunneling transport through six-layer h-BN sandwiched between Ru electrodes.

### DETAILED DESCRIPTION

The present disclosure is directed to a method for forming high quality hexagonal boron-nitride films. The disclosed method may produce scalable, high quality, uniform bi-layer and few-layer hexagonal boron nitride (h-BN) dielectric films. The scalability and adaptability of the disclosed method can be achieved, for example, by using reactive radio frequency magnetron sputtering of boron in N₂/Ar with a scalable, industry-compatible process that uses benign, non-toxic reagents.

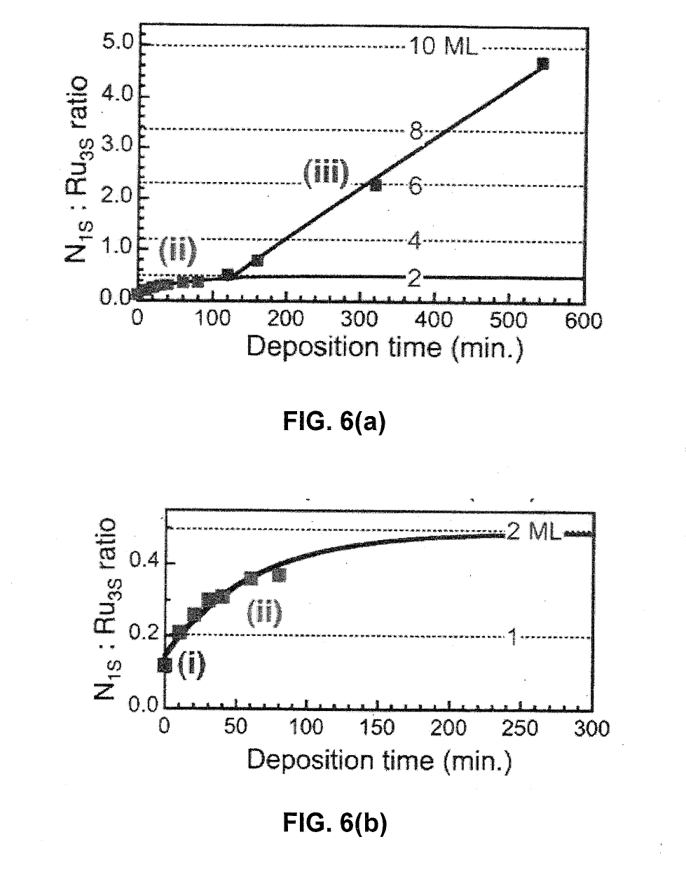

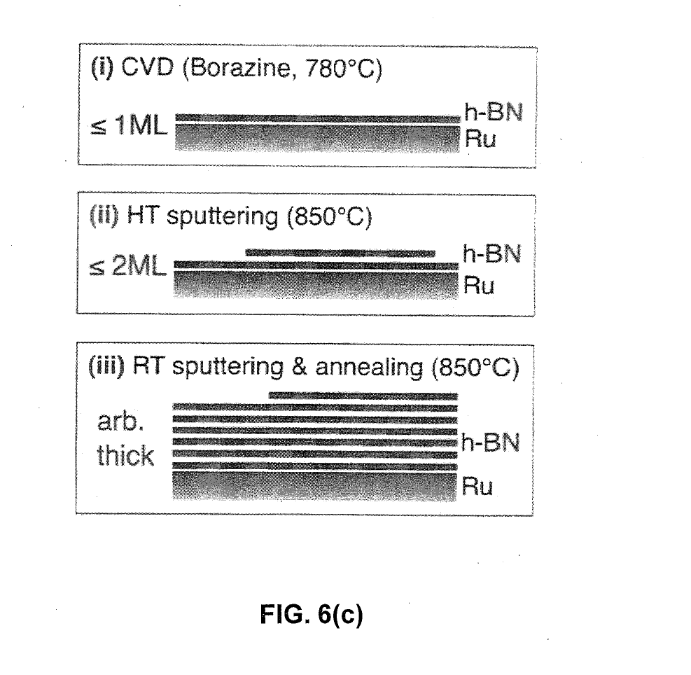

The disclosed method for forming high quality hexagonal boron-nitride films is essentially exemplified in FIG. 6, in particular FIG. 6(c), panels ii and iii. One embodiment of the method provides a method of reactive radio frequency magnetron sputtering of a boron target in high-purity Ar/N₂ gas mixtures at elevated temperature to form a high-quality bi-layer of h-BN on a substrate. Another embodiment provides methods for forming few-layer h-BN film on a substrate comprising alternatingly depositing thereon a layer of boron-nitride by reactive radio frequency magnetron sputtering of a boron target in high-purity Ar/N₂ gas mixtures at room temperature and annealing the deposited layer at elevated temperature until the desired number of layers of h-BN has been formed on the substrate. One embodiment of the method further includes providing a bilayer of h-BN on a substrate by high temperature sputtering and thereafter depositing additional layers by alternatingly depositing thereon a layer of boron-nitride by reactive radio frequency magnetron sputtering of a boron target in high-purity Ar/N₂ gas mixtures at room temperature and annealing the deposited layer at elevated temperature until the desired number of additional layers of h-BN has been formed on the provided bi-layer of h-BN. In some embodiments, the substrate comprises a Ru film on Al₂O₃. In a preferred embodiment said substrate comprises an epitaxial Ru film on αAl₂O₃ (0001) (c-plane sapphire). Adjustable parameters (e.g., Temperature, Time, Pressure, Power, etc.)

As noted above, the method for forming hexagonal boron-nitride film is scalable and adaptable to control the thickness of the film. The scalability and adaptability of the disclosed method can be achieved, for example, by adjusting various parameters used in the reactive magnetron sputtering. These parameters include temperature, time, pressure, and power among others.

The bi-layer of boron-nitride can be formed at any temperature. In one embodiment, the boron-nitride bi-layer is formed at room temperature or higher. In a specific embodiment, the boron-nitride bi-layer is formed at a temperature between about 800° C. to about 1200° C. In a specific embodiment, the reactive radio frequency magnetron sputtering at elevated temperatures (800-1200° C.) yields boron-nitride films bi-layers that are high quality and uniform in thickness.

The formation of few-layer boron-nitride films by magnetron sputtering a boron target in high-purity Ar/N₂ gas mixtures can proceed for any desired time. In certain embodiments, the magnetron sputtering continues for the appropriate length of time required to form a self-terminating bi-layer of hexagonal boron-nitride. In an embodiment, the magnetron sputtering continues for a period of about 30 to about 150 minutes, at which time a high quality bi-layer hexagonal boron-nitride film is formed. The appropriate amount of time to form each of the additional layers of hexagonal boron-nitride can be determined and configured based upon the rate of formation of each preceding layer of boron-nitride by magnetron sputtering.

Further, the reactive radio frequency magnetron sputtering can be performed at any pressure. In an embodiment, the sputtering takes place in a vacuum system. In another embodiment, the total pressure of the vacuum system can be from about 10⁻¹ to about 10⁻⁴ Torr.

The radio frequency power delivered to the target in the reactive magnetron sputtering can vary and be adjusted depending on the specific design of the apparatus used for said sputtering process. In an embodiment, the magnetron sputtering may occur with about 10 W rf power.

The annealing of the hexagonal boron-nitride can occur for various times and at various temperatures in the disclosed method.

In one embodiment, the method includes (a) forming a first layer of boron-nitride on a substrate by reactive radio frequency magnetron sputtering of a boron target in high-purity Ar/N₂ gas mixtures at room temperature; and (b) annealing said first layer and repeating (a) and (b) until a desired number of layers of h-BN are deposited. That is, the annealing occurs after each layer of boron-nitride is formed on the preceding, annealed layer.

In an alternate embodiment, the method for forming high quality few-layer hexagonal boron-nitride films includes (a) forming a bi-layer of boron-nitride on a substrate by reactive radio frequency magnetron sputtering of a boron target in high-purity Ar/N₂ gas mixtures at elevated temperature; and (b) alternatingly sputtering at room temperature to deposit an additional layer and annealing said additional layer at elevated temperature

In an embodiment, the annealing occurs for approximately 40 minutes. In another embodiment, the elevated annealing temperature may be from 800° C. to about 1200° C.

The hexagonal boron-nitride film can be formed on any suitable substrate. For example, the substrate may include, but is not limited to: metals (e.g., Ru, Ni, Cu, Co, Fe; Ag, Pd, Rh, Au, Pt, Ir), semimetals (in particular graphene), semiconductors (e.g., C, Si, Ge, Sn, TiO₂, GaAs and other compound semiconductors), metal dichalcogenides (e.g., MoS₂, MoSe₂, WS2, WSe₂), and insulators (e.g., Al₂O₃, MgO, HfO, LaO). In an embodiment, the substrate may be ruthenium.

In an embodiment, the ruthenium substrate comprises a single-crystalline, epitaxial Ru film on α-Al₂O₃(0001) (c-plane sapphire). In other embodiments, the ruthenium substrate may be approximately 100 nm thick.

The present disclosure is also directed to a product that is a scalable, high quality bi-layer or few-layer hexagonal boron-nitride dielectric film wherein the atomic layers can be substantially parallel to the substrate. Also, the few-layer hexagonal boron-nitride films are comprised of atomic layers being planar and having a substantially equal and uniform thickness.

### EXAMPLES

Reference will be made in detail to embodiments, examples of which are illustrated in the accompanying drawings. The disclosed embodiments may have different forms and should not be construed as being limited to the descriptions set forth herein. Accordingly, the embodiments are merely described below, by referring to the figures, to explain aspects of the present description.

### Example 1

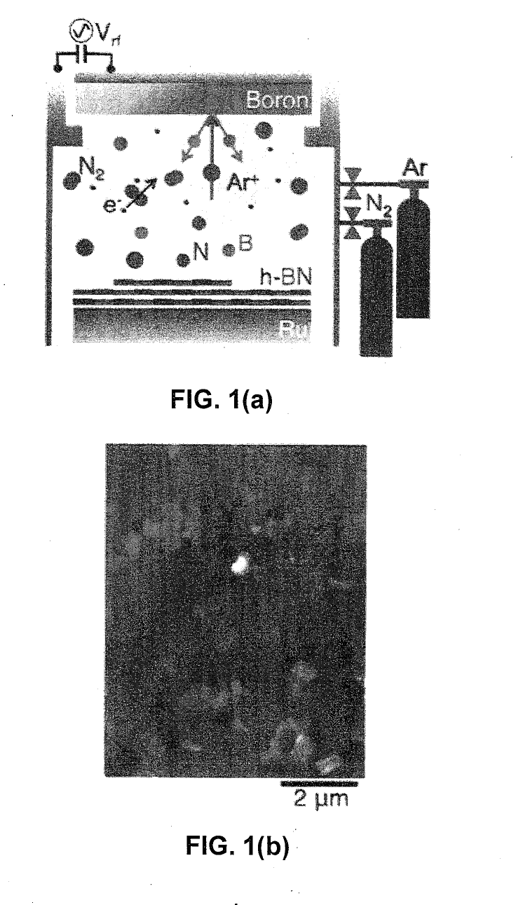

The glow discharge of the magnetron sputtering process plays two important roles in the growth of BN films (see FIG. 1(a)): (i) evaporation of B by collision cascades due to the impact of energetic noble gas (such as here, Ar⁺) ions on a solid B target; and (ii) generation of nitrogen (N) radicals via dissociation of gas phase di-nitrogen (N₂) by free electrons and ions in the plasma. On an appropriate substrate (here epitaxial Ru(0001) thin films) heated to high temperature, B and N species assemble into a well-ordered film consisting of layered atomic h-BN sheets (see FIG. 1(b)).

FIGS. 1(a)-(b) show hexagonal boron nitride growth by reactive magnetron sputtering. FIG. 1(a) depicts a schematic diagram of the planar magnetron geometry for deposition from a solid boron target in Ar/N₂ gas. FIG. 1(b) depicts ultra-high vacuum (UHV) scanning electron micrograph of the surface of a three layer h-BN film on epitaxial Ru(0001)/Al₂O₃. The secondary electron intensity scales with the BN thickness.

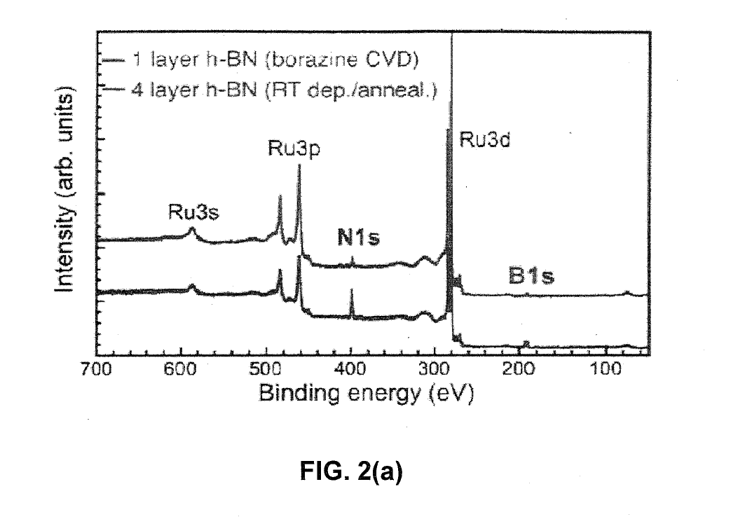

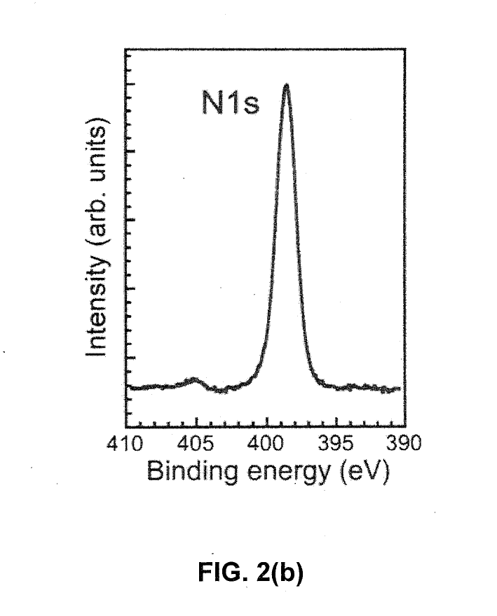

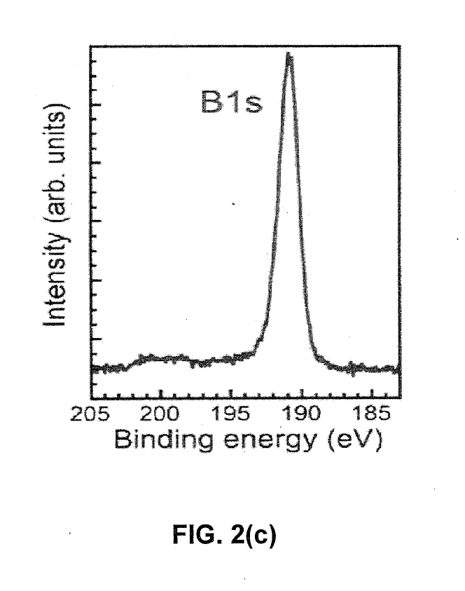

Optimum growth conditions produce crystalline stacks of BN atomic layers with low thickness variation (±1 layer) across the entire sample and consistent [B]/[N] atomic ratios of (1.0±0.05), confirming BN stoichiometry. This can be determined from the intensities of B1s and N1s core levels in X-ray photoelectron spectroscopy (XPS). FIGS. 2(a)-(c) show XPS analysis of 1-layer and 4-layer h-BN films on Ru(0001). FIG. 2(a) shows a survey XPS scan of samples grown by borazine chemical vapor deposition (CVD) [1 BN layer], and by alternating room temperature magnetron sputter deposition and 850° C. annealing [4 BN layers], FIG. 2(b) N1s peak and FIG. 2(c) B1s peak of the 4-layer film.

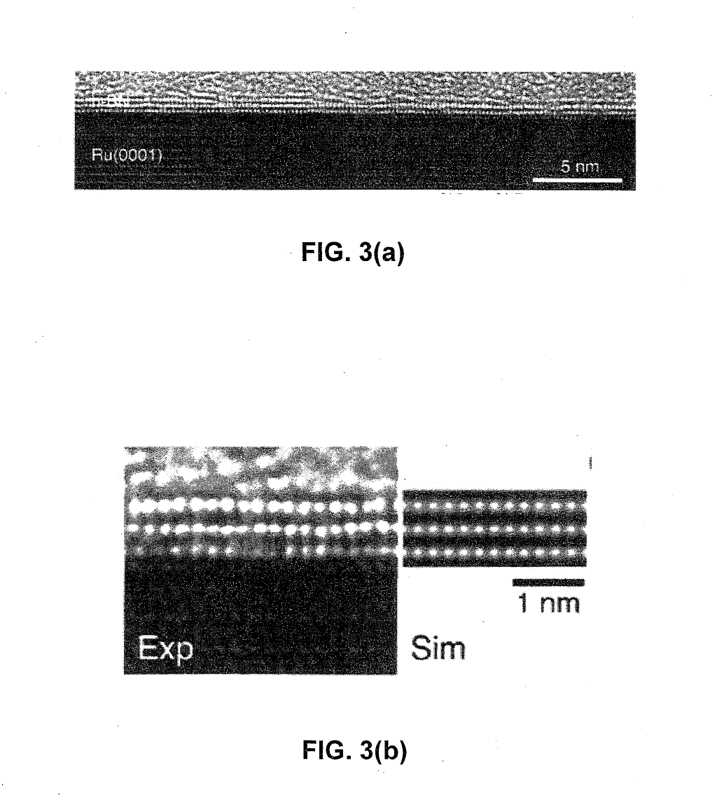

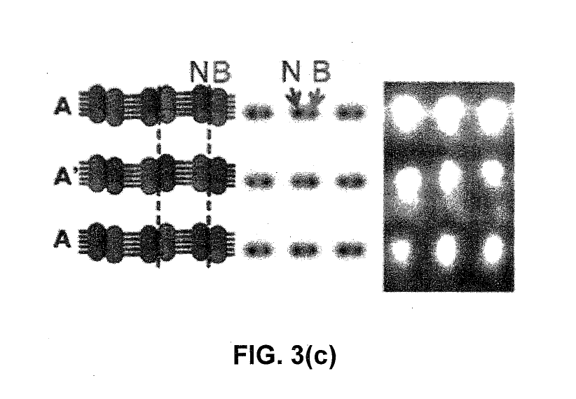

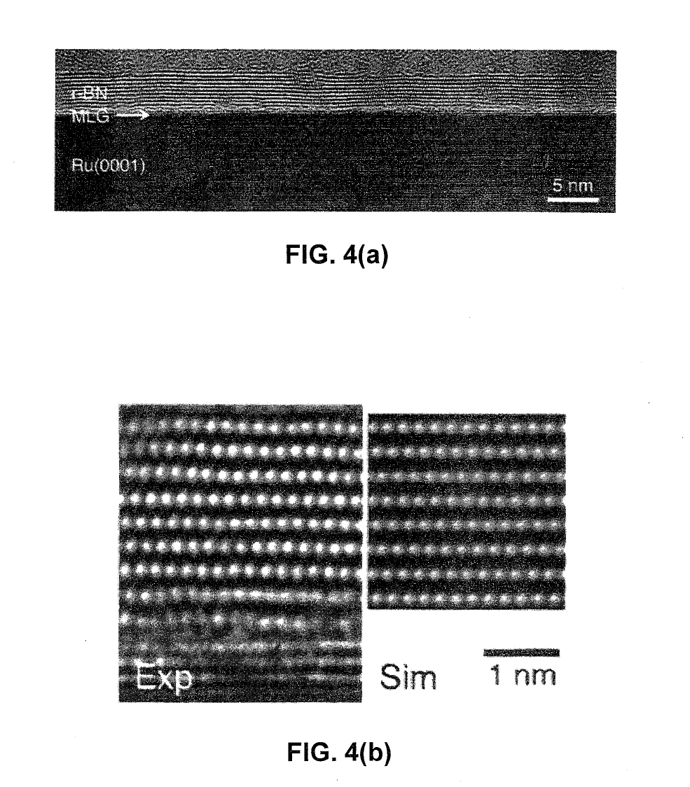

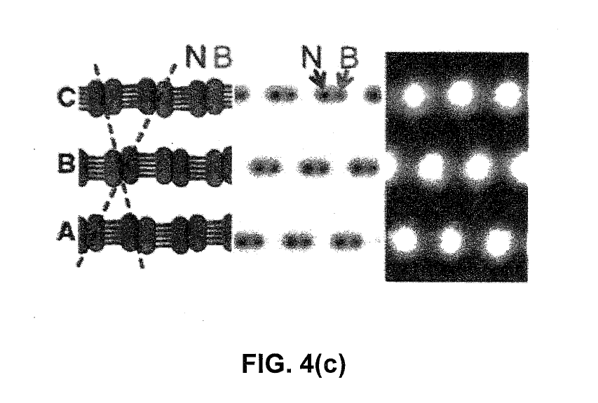

Apart from the equilibrium h-BN phase, thin film deposition at temperatures far below those used for growing BN single crystals can give rise to well-ordered metastable crystalline phases, such as rhombohedral BN (rBN), a BN polymorph in which honeycomb atomic BN layers are arranged in non-equilibrium A-B-C stacking order. In BN growth by magnetron sputtering on Ru, the termination of the metal surface determines the layer stacking and hence the BN phase that forms. Whereas direct growth onto clean Ru(0001) produces hexagonal BN (A-A′-A stacking; see FIG. 3), the termination of the Ru surface with a graphene monolayer prior to BN growth induces a different stacking order (A-B-C; see FIG. 4), that is, produces rhombohedral BN.

FIGS. 3(a)-(c) show A-A′-A stacked hexagonal BN on Ru(0001). FIG. 2(a) shows an overview HRTEM image of a three-layer BN film. FIG. 2(b) shows a comparison of the experimental contrast with a dynamic image simulation assuming the equilibrium A-A′-A stacking of hexagonal BN. FIG. 3(c) shows a model of A-A′-A stacked hexagonal BN, a computed electron density map, and the experimental HRTEM image.

FIGS. 4(a)-(c) show A-B-C stacked rhombohedral BN on graphene-covered Ru(0001). FIG. 4(a) shows an overview HRTEM image of a 10-layer BN film. FIG. 4(b) shows a comparison of the experimental contrast with a dynamic image simulation assuming nonequilibrium A-B-C stacking. FIG. 4(c) shows a model of A-B-C stacked rhombohedral BN, a computed electron density map, and the experimental HRTEM image.

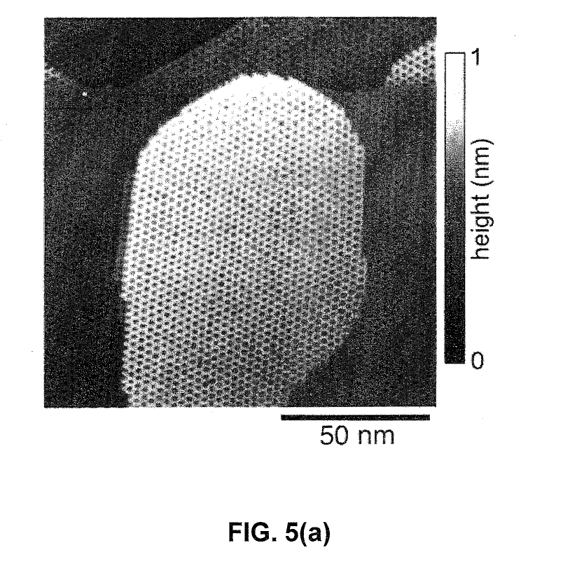

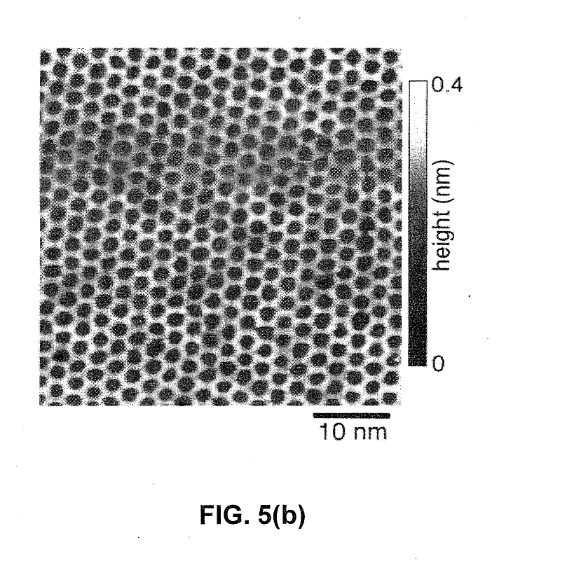

Monolayers of both graphene and boron nitride on Ru(0001) have complex moiré structures, either a BN nanomesh for BN growth directly onto Ru(0001), (see FIG. 5), or a graphene moiré with inhomogeneous charge distribution in the two C sublattices. FIGS. 5(a)-(b) show STM imaging of thin BN/Ru(0001) [˜1.3 atomic layers BN coverage] grown by magnetron sputtering at 850° C.: FIG. 5(a), survey scan; and FIG. 5(b), high magnification image of the h-BN ‘nanomesh’ surface structure. The different structures of the first layer (either graphene or BN terminated, i.e., showing either a graphene/Ru or BN/Ru moiré structure) are key to understanding the different stacking sequences induced in thicker BN films by these first (interfacial) layers. Calculations show rBN and conventionally stacked h-BN nearly degenerate in the bulk, but the results suggest that different interface configurations favor different incipient stacking sequences (A-A′ or A-B) defined by the first BN sheet beyond the interfacial layer, which then persist for the entire thickness of the BN film (see FIG. 4). While A-A′-A stacked h-BN and A-B-C stacked rBN have similar electronic structures, that is, they likely show comparable dielectric properties, control over the stacking sequence can add significantly to the tools for BN materials processing. For example, the kinetics of conversion of the two hexagonal BN phases to cubic (zincblende) c-BN should be very different, with rBN transforming along a facile, diffusionless pathway. Selective growth of single crystalline rBN is a basis for the formation of ultrathin, high-quality cubic BN films.

The realization of ordered crystalline films with well-defined sequence of atomic layers and controlled overall thickness (i.e., achieving a desired number of atomic layers) is an important requirement for a rational BN synthesis method. The preparation of uniform single monolayer BN on metals has been facilitated by the low chemical reactivity of the h-BN surface, which leads to a self-termination of growth by low-pressure borazine CVD after the completion of a monolayer film (See FIG. 6 (i)). FIGS. 6(a)-(c) show a comparison of the regimes of few-layer h-BN growth by chemical vapor deposition and reactive magnetron sputtering. FIGS. 6(a) and 6(b) show XPS analysis of N1s to Ru3s core level intensity ratio for growth by: (i) low pressure CVD using borazine (780° C.); (ii) reactive magnetron sputtering at high temperature (850° C.); and (iii) alternating room temperature sputtering and annealing to 850° C. FIG. 6(c) shows a schematic representation of the thickness regimes accessible by the different h-BN growth methods.

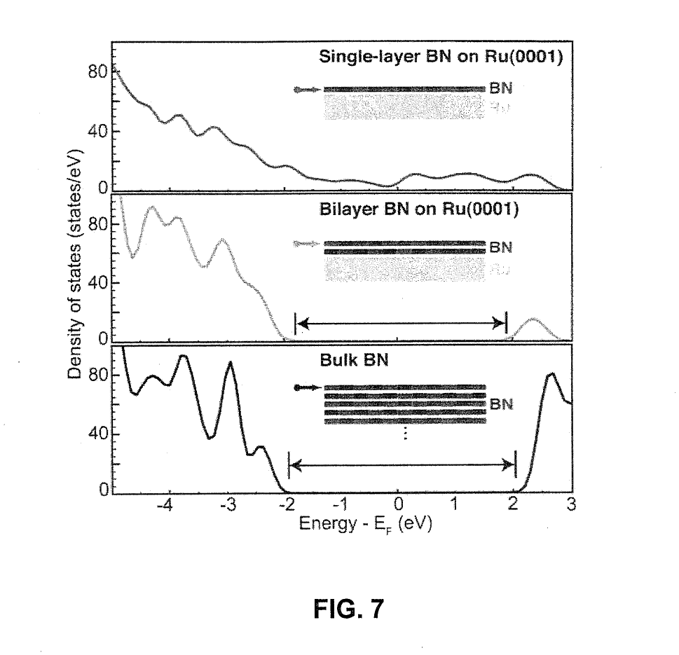

In comparison with monolayer BN growth, which can readily be accomplished by CVD methods, the synthesis of few-layer BN films with uniform thickness is significantly more challenging and has not been achieved by CVD. Different scenarios have been identified in reactive magnetron sputtering that provide high-quality BN films with good thickness uniformity. Via deposition at high substrate temperatures (800° C.-1000° C.), high quality bi-layer films are obtained. Analysis by XPS shows a progressive reduction of the growth rate such that two complete BN layers are only achieved asymptotically (FIG. 6 (c) (ii)). The slowing of the growth rate and apparent inability to realize films with more than two atomic layers using slow deposition at high substrate temperature is consistent with a thickness-dependent sticking coefficient of the deposited B/N species on the BN surface. The first BN layer is readily achieved due to the high reactivity and sticking coefficient of the metal surface. The observed saturation coincides with the transition from a still moderately reactive, corrugated interfacial BN layer to a BN bilayer with much lower surface reactivity approaching that of bulk BN. The drop in reactivity at a thickness of 2 BN layers is corroborated by ab initio calculations of the projected density of states (DOS; FIG. 7), and of the binding energy of a B₃N₃ radical used to model adsorption on the BN surface. Monolayer BN on Ru shows a finite DOS near the Fermi level (E_{F}) and a high binding energy of B₃N₃ (0.9 eV). For bilayer BN on Ru, a large bandgap comparable to that of bulk BN opens up. The DOS at E_{F} is negligible, and the computed B₃N₃ binding energy (0.5 eV) becomes equal to that on bulk BN (see generally FIGS. 2, 5, 7-11); that is, adsorption of B/N species and BN nucleation beyond two layers are suppressed.

FIG. 7 shows computational results on the reactivity of the surfaces of single- and bilayer h-BN on Ru(0001), and comparison with bulk h-BN. Monolayer BN/Ru(0001) shows a finite projected density of states (DOS) near the Fermi energy (E_{F}). At the surface of bilayer BN/Ru(0001) a large bandgap with negligible DOS opens up, comparable to the gap found for bulk BN. The low DOS near E_{F} indicates a low reactivity of the surface of bilayer BN. The same trend is reflected in the calculated binding energy of a B₃N₃ radical on these surfaces. Whereas a B₃N₃ binds strongly on monolayer BN/Ru(0001) (binding energy 0.9 eV), the binding energy on bilayer BN/Ru(0001) is indistinguishable from that on the inert bulk BN surface (0.5 eV).

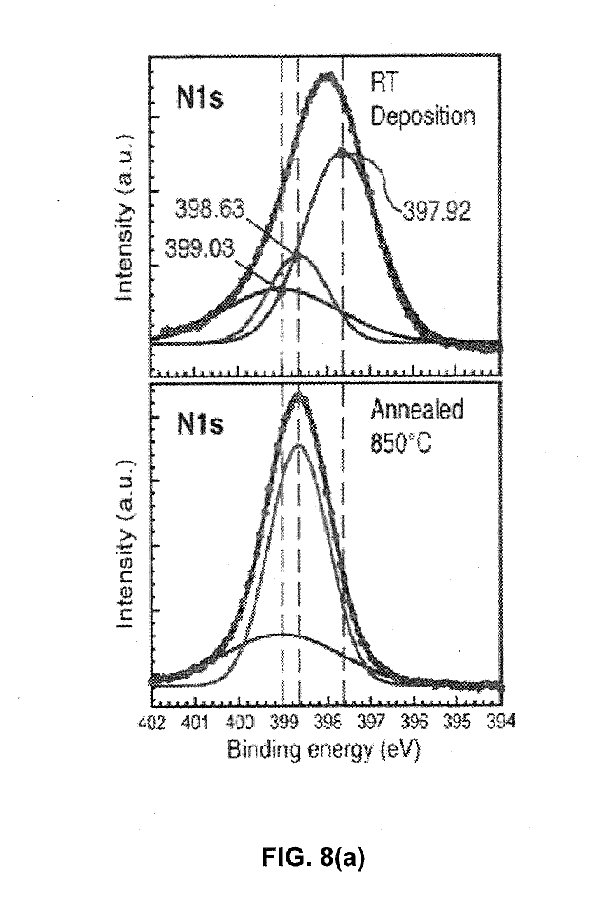

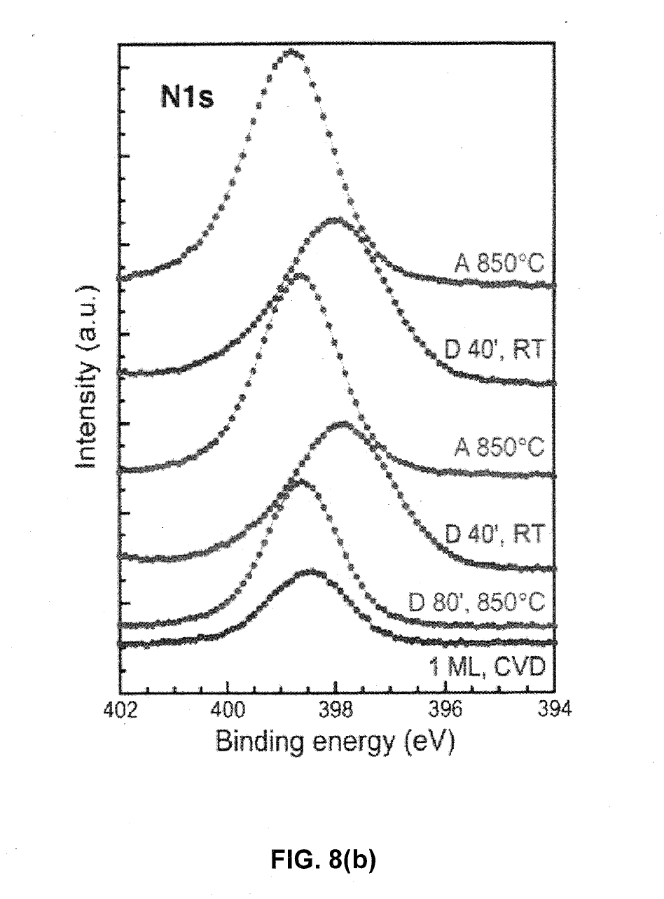

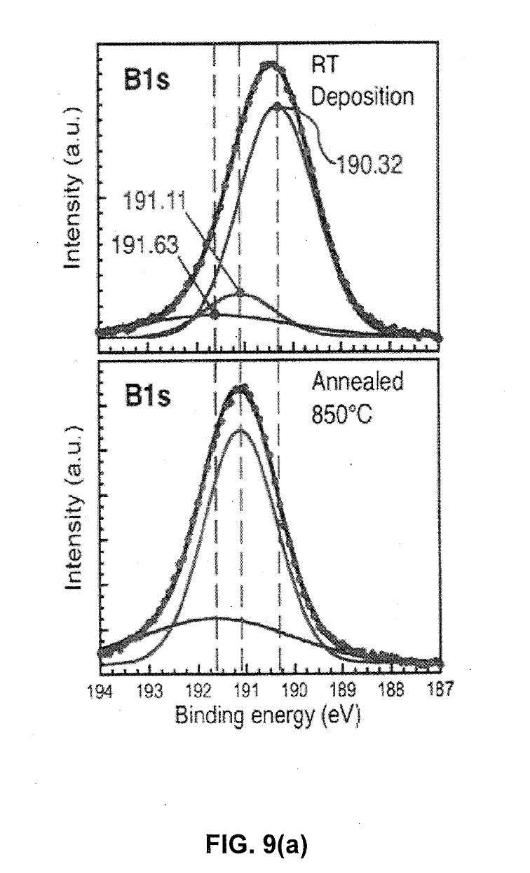

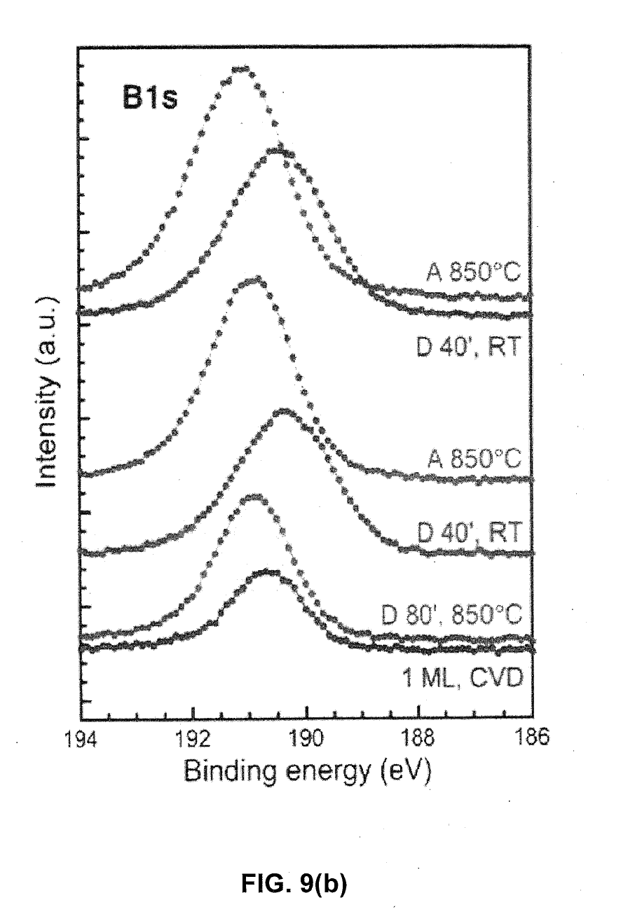

The two-layer limit can be overcome by an alternative growth scenario (FIG. 6 (c) (iii)). Reactive sputtering onto substrates held at room temperature involves a constant, thickness-independent BN deposition rate close to the initial rate observed for high temperature growth, consistent with a high sticking coefficient of the deposited species. Room-temperature deposition produces amorphous or nanocrystalline BN films, whose N1s and B1s XPS spectra are dominated by peaks that are red-shifted (by 0.71 and 0.79 eV, respectively) compared to those of well-ordered, crystalline h-BN synthesized at high temperature (see FIGS. 8 and 9). Thin nanocrystalline BN films are recrystallized by vacuum annealing to 850° C. or above, which eliminates the red-shifted XPS lines and transfers the entire spectral weight into the characteristic peaks of well-ordered, crystalline h-BN. Via alternating deposition of the equivalent of ˜1 BN atomic layer in nanocrystalline form and crystallization at high temperature, layered h-BN films with controlled thickness uniformity (±1 layer) are realized on epitaxial Ru(0001)/Al₂O₃ substrates (FIGS. 3, 4, and 6). Use of a thin nanocrystalline precursor layer ensures that only short-range mass transport and rebonding are required to form a new h-BN sheet, whereas the already completed layers act as an inert support. The stoichiometric [B]/[N] ratio, that is, absence of any detectable N loss, suggests that the deposited B—N species remain intact while becoming part of the growing crystalline sheet during annealing. This overall scenario is similar to the annealing of polyborazylene on Ni (Shi, Y.; 2010), which results in crystalline h-BN but has not shown atomic-layer thickness control.

FIGS. 8(a)-(b) show an analysis of the N1s peak shape for alternating room temperature BN deposition by reactive magnetron sputtering and annealing. FIG. 8(a) shows a comparison of the N1s line shape after room temperature BN growth by reactive magnetron sputtering (top), and following annealing at 850° C. FIG. 8(b) shows N1s line shape after 1-layer borazine CVD growth of h-BN/Ru(0001), high-temperature ˜2-layer growth by magnetron sputtering, and alternating room temperature deposition (D) and annealing (A).

FIGS. 9(a)-(b) show alternating room temperature BN deposition and annealing-analysis of the B1s peak shape. FIG. 9(a) shows a comparison of the B1s line shape after room temperature BN growth by reactive magnetron sputtering (top), and following annealing at 850° C. FIG. 9(b) shows N1s line shape after 1-layer borazine CVD growth of h-BN/Ru(0001), high-temperature ˜2-layer growth by magnetron sputtering, and alternating room temperature deposition (D) and annealing (A).

### Example 2

Formation of uniform few-layer hexagonal boron-nitride dielectric films include a ruthenium substrate. In one embodiment, a substrate comprising single-crystalline, epitaxial Ru films on α-Al₂O₃(0001) (c-plane sapphire), deposited in situ, is used. The Ru film is preferably between 50 nm and 500 nm thick.

A single-step growth of a bi-layer h-BN film is achieved by employing reactive magnetron sputtering at elevated temperature. Alternating room temperature sputtering deposition with elevated temperature annealing is used to form a desired number of layers for a few-layer h-BN film. The room temperature sputtering deposition, in one embodiment, occurs for 30 to 150 minutes. The annealing occurs at a temperature of about 850° C. for about 30 minutes. Further, a high-temperature heater is used to cycle the substrate temperatures between room temperature and 1000° C., which may be preferably measured by an IR pyrometer.

### Example 3

The BN films can be characterized in situ by X-ray photoelectron spectroscopy (XPS) using Al K a radiation and by room temperature scanning tunneling microscopy (STM). Ex situ analysis can be performed by transmission electron microscopy (TEM) of cross sections of the films in a FEI Titan 80-300 microscope equipped with a CEOS Cs-corrector at 300 keV electron energy. Thin sections for TEM can be prepared by focused ion beam milling. High-resolution TEM contrast simulations can be carried out using the multislice method, as implemented in the software package JEMS. Further characterization can be performed by UHV scanning electron microscopy (Zeiss Gemini), tapping mode atomic force microscopy (Veeco Nanoscope V), and Raman spectroscopy (WiTec Alpha 300) using 532 nm excitation, a 100× objective (spot size 400 nm), and incident power below 1 mW. UV-visible spectroscopy has been measured in an integrating sphere reflection geometry using a Perkin-Elmer Lambda 950 UV-vis/NIR spectrophotometer. The optical bandgap, E_{g}, can be determined from the photon-energy dependent absorption coefficient α(E) using the relation (α•E)²=C(E−E_{g}) for a direct-gap material.

The thickness and composition of the BN films can be determined, from XPS measurements by analyzing the intensities of Ru3s/N1s and N1s/B1s peaks, respectively. The thickness analysis takes into account the different photo-emission cross sections (Scofield factors) at hv=1486 eV, as well as the inelastic mean free paths of the Ru3s and N1s photoelectrons. In the analysis of the h-BN composition, the difference in mean free paths for N1s and B1s photoelectrons amounted to intensity differences below 2% for the thickest films (˜10 BN layers) and can therefore be neglected.

Test structures for tunneling transport experiments were fabricated by thermal evaporation of arrays of Ru disk electrodes (2 pm diameter, 5 nm thick) in UHV onto well-degassed BN/Ru(000I) thin films, using SiN shadow masks (50 nm thick, 2 pm openings; TEMwindows SN100-MP2Q05) aligned using a Nanostencil shadow mask lithography system. Samples with Ru—BN—Ru sandwich structures were transferred in situ to a UHV nanomanipulation system for electrical transport measurements (Omicron UHV Nanoprobe). The bottom contact was made to the Ru thin film of the substrate, whereas the top Ru disk electrodes were contacted by using electrochemically sharpened W tips. The tip approach was accomplished using a tunneling (STM) feedback loop, and mechanical contact to the Ru electrodes then established by decreasing the tip-sample distance (viewed by field-emission SEM) until stable, reproducible current-voltage characteristics were obtained. Current-voltage curves were measured with the sample held at room temperature, using a programmable semiconductor test system (Keithley, model 4200SCS).

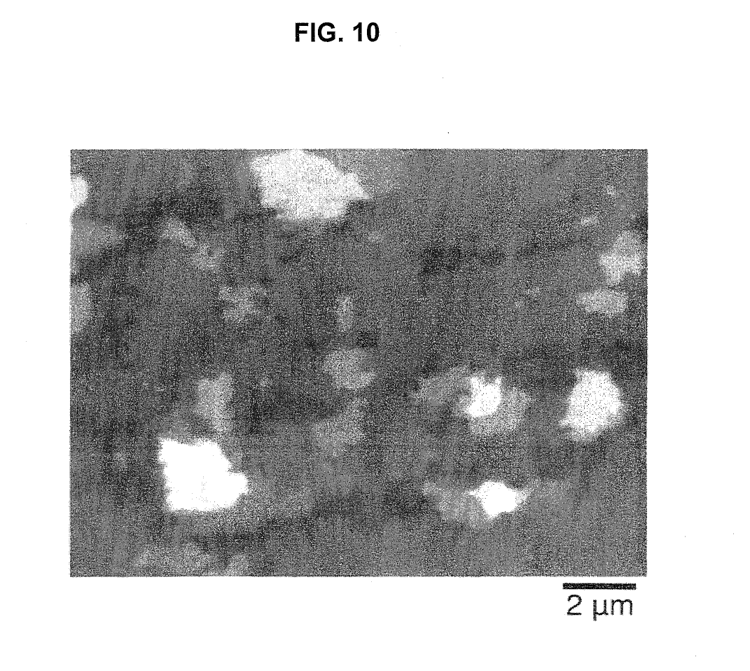

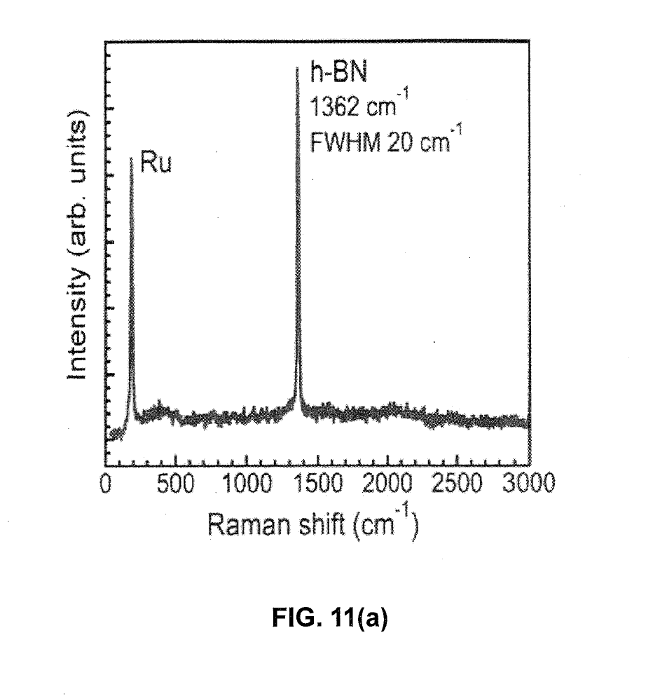

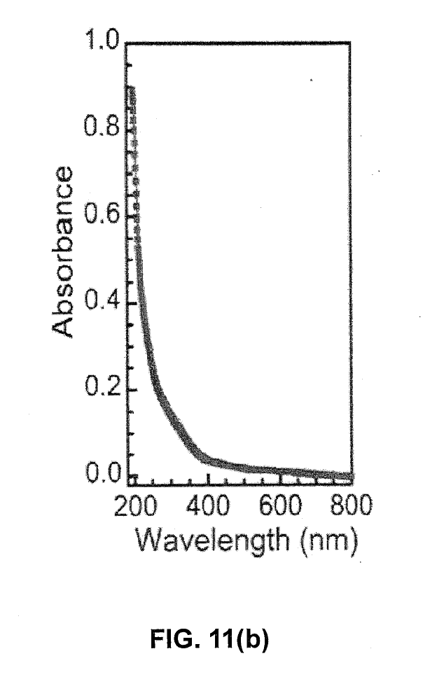

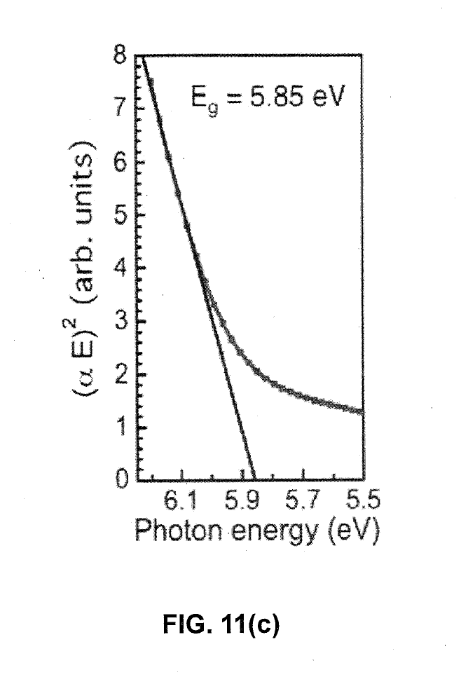

Ultrahigh vacuum (UHV) scanning electron microscopy on thicker BN films shows a well-ordered surface consisting of pm-sized terraces with uniform height delineated by sharp steps, consistent with the expected appearance of atomic layers in high quality h-BN (See FIG. 10). FIG. 10 shows UHV scanning electron microscopy image of a thicker (˜6 layer) BN film on Ru(0001). Raman spectroscopy on annealed films detects a narrow line due to the E_{2g} zone center mode at 1362 cm⁻¹ (see FIG. 11(a)). The optical properties of few-layer BN films on Ru(0001) have been investigated by UV-visible absorption spectroscopy (FIG. 11(b),(c)). A 10-layer BN film shows low absorbance in the near-infrared and visible spectral range and a sharp increase in absorption at UV wavelengths (See FIG. 11(b)), as expected for a large-bandgap dielectric. Analysis of the UV absorption (See FIG. 11(c)) yields a direct optical bandgap of (5.85±0.05) eV, in good agreement with measurements on thicker crystalline BN layers and BN single crystals.

FIGS. 11(a)-(c) show optical UV/Vis and Raman spectroscopy on few-layer BN/Ru(0001). FIG. 11(a) shows Raman spectrum obtained near an edge of a BN film lifted off from the Ru substrate, showing sharp lines due to the transverse optical zone center phonon mode of Ru at ˜190 cm⁻¹, and the E_{2g} zone center mode of h-BN at 1362 cm⁻¹. FIG. 11(b) shows UV/Vis spectrum obtained in reflection geometry on a 10 layer h-BN film on Ru(0001). FIG. 11(c) shows an analysis of the energy dependent absorbance of the film, showing an optical bandgap E_{g}=5.85 eV.

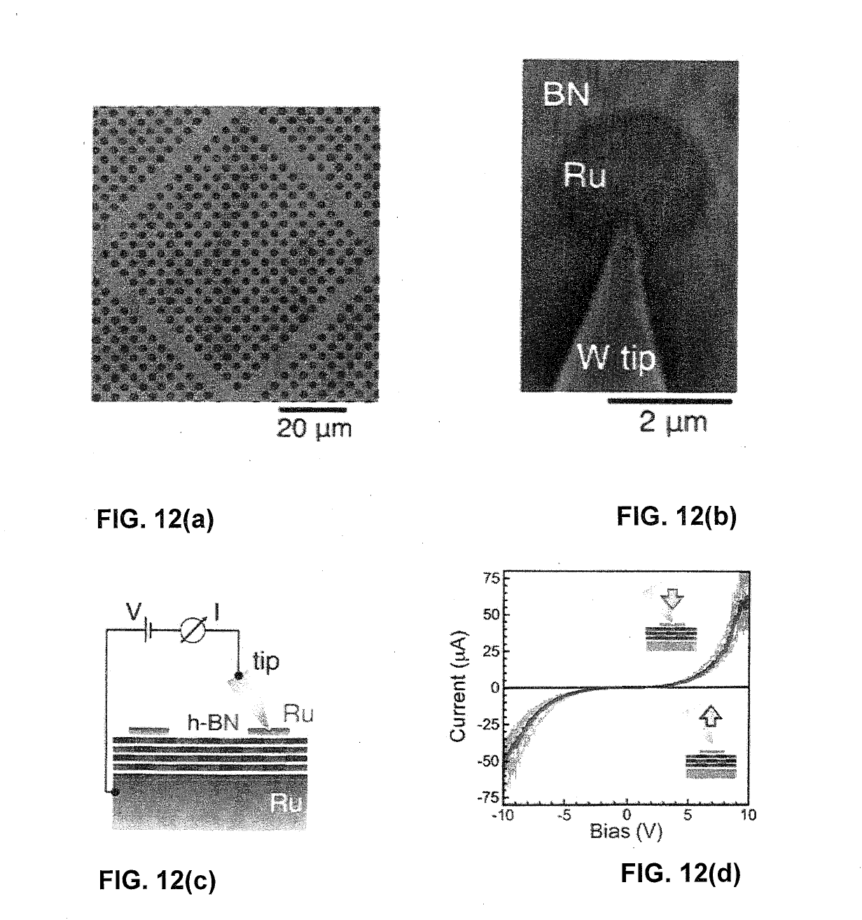

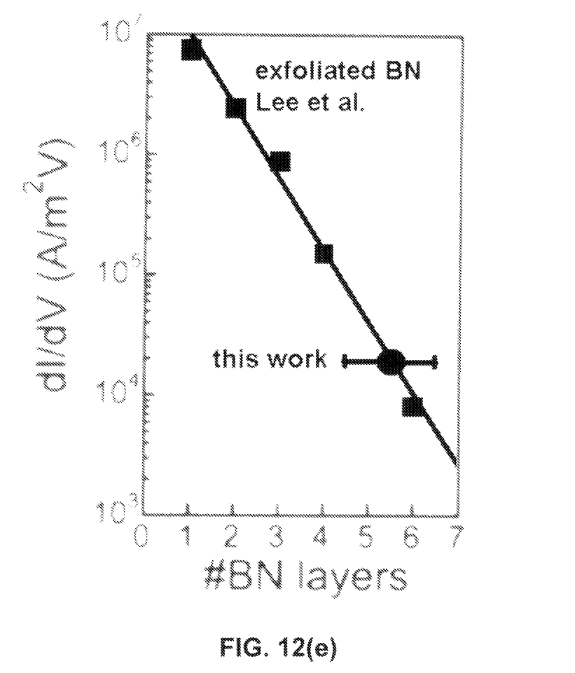

The dielectric properties of the few-layer h-BN films can be evaluated by fabricated test structures in which the active BN layer is sandwiched between the Ru(0001) substrate and thin, circular Ru top electrodes defined by shadow mask deposition in UHV (See FIG. 12(a)). Individual device structures were addressed via three-axis nanomanipulated probe tips for vertical transport measurements (see FIGS. 12(b) and (c)). The results of representative measurements are summarized in FIGS. 12(d) and (e).

FIGS. 12(a)-(e) shows vertical transport through six layer h-BN sandwiched between Ru electrodes. FIG. 12(a) shows UHV SEM image of a Ru top electrode pattern fabricated in situ by shadow mask deposition of Ru onto six layer h-BN/Ru(0001). FIG. 12(b) shows UHV SEM image of one of the Ru electrodes (2 μm diameter) contacted by a W probe tip. FIG. 12(c) shows a schematic of the vertical transport measurement on h-BN between Ru electrodes. FIG. 12(d) shows current voltage characteristics measured with the W probe tunneling above (dark rectangles) and in contact with (light rectangles) the top Ru electrode. Dark trace: average over 10 individual measurements shown as gray lines. FIG. 12(e) shows a comparison of the specific tunneling conductance of a BN/Ru(0001) film grown by reactive magnetron sputtering (six layers thick) with that of exfoliated BN (Lee, G.-H. “Electron tunneling through atomically flat and ultrathin hexagonal boron nitride” Appl. Phys. Lett. 2011, 99, 243114-243113), normalized to the device area.

Tunneling current-voltage (I-V) characteristics consistently show a small, linearly increasing current at low bias, followed by a transition to an exponential rise in current signaling the onset of dielectric breakdown in the BN film in the high-bias regime (see FIG. 12(d)). Similar to graphene, exfoliation of BN from bulk crystals or powders provides few-layer material with very low defect density that can serve as a benchmark for the quality of bottom-up synthesized BN films. Comparing the I-V characteristics of micrometer-scale structures of six-layer BN (grown by alternating room temperature deposition and annealing (see FIG. 6 (c) (iii)) sandwiched between Ru electrodes with recent measurements within small diameter (25 nm) contact areas on exfoliated BN, low-bias tunneling conductances are found to be consistent with direct tunneling through (6±1) atomic layers of h-BN (FIG. 12e), that is, pinhole-free, uniform dielectric behavior over the ˜3 μm² active areas of the devices.

Previous work on BN growth on metal foils (Cu, Ni) has made evident a need to isolate the films and transfer them to other supports for possible use in devices, such as UV light emitters. High-quality few-layer BN on epitaxial metal thin films offer the opportunity of a bottom-up assembly of a device structure comprising an insulating substrate, metallic gate contact and BN dielectric and ultimately the active channel of a graphene field-effect device. This can be achieved without metal etching or layer transfers, or in the substantial absence of metal etching or layer transfers.

The disclosed embodiments for the synthesis of high quality few-layer hexagonal BN films with good layer thickness uniformity provides an avenue for , and represents an important step toward developing the bottom-up synthesis of graphene-BN hybrid layered materials. The disclosed method can also be directed to the growth of graphene layers on BN, and the fabrication of devices and engineered heterostructures comprising alternating graphene and BN layers with controlled thickness.

The description has not attempted to exhaustively enumerate all possible variations. That alternate embodiments may not have been presented for a specific portion of the invention, and may result from a different combination of described portions, or that other non-described alternate embodiments may be available for a portion, is not to be considered a disclaimer of those alternate embodiments. It will be appreciated that many of those non-described embodiments are within the literal scope of the following claims, and others are equivalent.

1. A method for forming, on a substrate, a high quality few-layer hexagonal boron-nitride film having a desired number of layers, comprising:
alternatingly, for each desired layer:
reactive radio frequency magnetron sputtering onto said substrate at room temperature a boron target in high-purity Ar/N₂ gas mixtures, and
annealing at elevated temperature
to form said high quality few-layer hexagonal boron-nitride film on the substrate having the desired number of layers.

2. The method of claim 1 wherein a bi-layer of high quality hexagonal boron-nitride film is first formed on said substrate by reactive radio frequency magnetron sputtering on the substrate at elevated temperature prior to forming the high quality few-layer hexagonal boron-nitride film having the desired number of layers.

3. The method according to claim 1, wherein said elevated temperature is between about 800° C. to about 1200° C.

4. The method according to claim 1, wherein said annealing occurs for approximately 40 minutes.

5. The method according to claim 1, wherein said substrate is selected from the group consisting of metals, semimetals, semiconductors, metal dichalcogenides, and insulators.

6. The method according to claim 5 wherein metals are selected from the group consisting of Ni, Cu, Co, Fe, Ag, Pd, Rh, Ru, Au, Pt, and Ir; the semimetals are selected from the group consisting of graphene, bilayer graphene, and few-layer graphene; the semiconductors are selected from the group consisting of C, Si, Ge, Sn, TiO₂ and GaAs; the metal dichalcogenides are selected from the group consisting of MoS₂, MoSe₂, WS₂, and WSe₂; and
the insulators are selected from the group consisting of Al₂O₃, MgO, HfO, and LaO.

7. The method according to claim 6, wherein said metal is ruthenium (Ru).

8. The method according to claim 7, wherein the ruthenium comprises single-crystalline, epitaxial Ru film on α-Al₂O₃(0001) (c-plane sapphire).

9. The method according to claim 8, wherein said single-crystalline, epitaxial Ru film is approximately 100 nm thick.

10. The method according to claim 1, wherein the reactive radio frequency magnetron sputtering takes place in a vacuum system that is a moderate to a high vacuum system.

11. The method according to claim 10, wherein said vacuum system includes pressures of about 10⁻¹ to about 10⁻⁴ Torr.

12. The method according to claim 1, wherein said reactive radio frequency magnetron sputtering occurs with 10 W rf power.

13. The method according to claim 1, wherein said boron target is 2 inches in diameter and 99.5% purity.

14. A boron-nitride film comprising two or more high quality hexagonal boron-nitride atomic layers on a substrate.

15. The boron-nitride film according to claim 14, wherein the hexagonal boron-nitride film comprises layers that are planar and substantially parallel to the substrate.

16. The boron-nitride film according to claim 14, wherein the hexagonal boron-nitride film comprises layers with substantially equal thickness.

17. A method for forming, on a substrate, a high quality bi-layer hexagonal boron nitride film comprising reactive radio frequency magnetron sputtering on the substrate at a temperature range of about 800° C. to about 1200° C. a boron target in a high-purity Ar/N₂ gas mixture for a time sufficient for formation of two layers of hexagonal boron nitride as the bi-layer hexagonal boron nitride film.

18. The method of claim 17 wherein the substrate is selected from the group consisting of metals, semiconductors, metal dichalcogenides, and insulators.

19. The method of claim 18 wherein the substrate metal is selected from the group consisting of Ni, Cu, Co, Fe, Ag, Pd, Rh, Ru, Au, Pt, and Ir.

20. The method of claim 19 wherein the substrate metal is Ru.
